(19) United States
(12) Patent Application Publication
(10) Pub. No.: US 2025/0279565 A1
(43) Pub. Date: Sep. 4, 2025

(54) RF PHASE SHIFTER

(71) Applicant: Murata Manufacturing Co., Ltd., Nagaokakyo-shi (JP)

(72) Inventors: Bo YANG, Kyoto-shi (JP); Naoki SHINOHARA, Kyoto-shi (JP); Tsuyoshi KAJIWARA, Kyoto-shi (JP); Takayuki OKADA, Nagaokakyo-shi (JP); Takaaki MIYASAKO, Nagaokakyo-shi (JP)

(21) Appl. No.: 19/214,149

(22) Filed: May 21, 2025

Related U.S. Application Data
(63) Continuation of application No. PCT/JP2023/033011, filed on Sep. 11, 2023.

(30) Foreign Application Priority Data
Dec. 2, 2022 (JP) 2022-193673

(51) Int. Cl. H01P 1/18; H03H 11/16

(52) U.S. Cl. CPC H01P 1/18; H03H 11/16

(57) ABSTRACT

An RF phase shifter includes a phase shifter to receive an input RF signal, generate an output RF signal in which a phase of the input RF signal is changed to a set phase in accordance with a control voltage, and output the output RF signal, a phase comparator to generate a phase difference voltage according to a phase difference between the input RF signal and the output RF signal, and a processor to generate a control voltage according to a voltage difference between the phase difference voltage and a reference voltage according to the set phase.

### CROSS REFERENCE TO RELATED APPLICATIONS

This application claims the benefit of priority to Japanese Patent Application No. 2022-193673 filed on Dec. 2, 2022 and is a Continuation Application of PCT Application No. PCT/JP2023/033011 filed on Sep. 11, 2023. The entire contents of each application are hereby incorporated herein by reference.

### BACKGROUND OF THE INVENTION

### 1. Field of the Invention

The present invention relates to RF phase shifters.

### 2. Description of the Related Art

An RF (high frequency) phase shifter that generates an output RF signal in which the phase of an input RF signal is changed to a set phase is known (for example, see Japanese Unexamined Patent Application, Publication No. H09-074325).

In such an RF phase shifter, highly accurate phase control is demanded. As a method of improving the accuracy of phase control of the RF phase shifter, fine phase shift control is considered. However, in a conventional RF phase shifter, there is an error of several degrees between the set phase and the output phase, and the accuracy of phase control is low. Therefore, the true value of the output phase is unknown, and it is difficult to ensure the accuracy of the phase control.

### SUMMARY OF THE INVENTION

Example embodiments of the present invention provide RF phase shifters each with highly accurate phase control.

An RF phase shifter according to an example embodiment of the present invention includes a phase shifter to receive an input RF signal, generate an output RF signal in which a phase of the input RF signal is changed to a set phase according to a control voltage, and output the output RF signal, a phase detector to generate a phase difference voltage according to a phase difference between the input RF signal and the output RF signal, and a processor to generate the control voltage according to a voltage difference between the phase difference voltage and a reference voltage according to the set phase.

An RF phase shifter according to another example embodiment of the present invention includes a digital phase shifter to receive an input RF signal, generate an output RF signal in which a phase of the input RF signal is changed to a set phase according to a digital control signal, and output the output RF signal, a phase detector to generate a phase difference voltage according to a phase difference between the input RF signal and the output RF signal, and a processor to generate the digital control signal according to a voltage difference between the phase difference voltage and a reference voltage according to the set phase.

According to example embodiments of the present invention, highly accurate phase control is provided in RF phase shifters.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic diagram showing an RF phase shifter according to an example embodiment of the present invention.

FIG. 2 is a circuit diagram showing an RF phase shifter (analog type) according to a first example embodiment of the present invention.

FIG. 3 is a circuit diagram showing an RF phase shifter (digital type) according to a second example embodiment of the present invention.

FIG. 4 is a circuit diagram showing an example of a phase shifter (digital type) in the RF phase shifter shown in FIG. 3.

FIG. 5 is a circuit diagram showing another example of the phase shifter (digital type) in the RF phase shifter shown in FIG. 3.

FIG. 6 is a circuit diagram showing an example of a variable reactance circuit (digital type) in the phase shifter shown in FIG. 4 or 5.

FIG. 7 is a circuit diagram showing another example of the variable reactance circuit (digital type) in the phase shifter shown in FIG. 4 or 5.

FIG. 8 is a circuit diagram showing another example of the variable reactance circuit (digital type) in the phase shifter shown in FIG. 4 or 5.

### DETAILED DESCRIPTION OF THE EXAMPLE EMBODIMENTS

Hereinafter, example embodiments of the present invention will be described in detail with reference to the accompanying drawings. In the drawings, the same or corresponding portions are denoted by the same reference numerals.

### First Example Embodiment

RF Phase Shifter

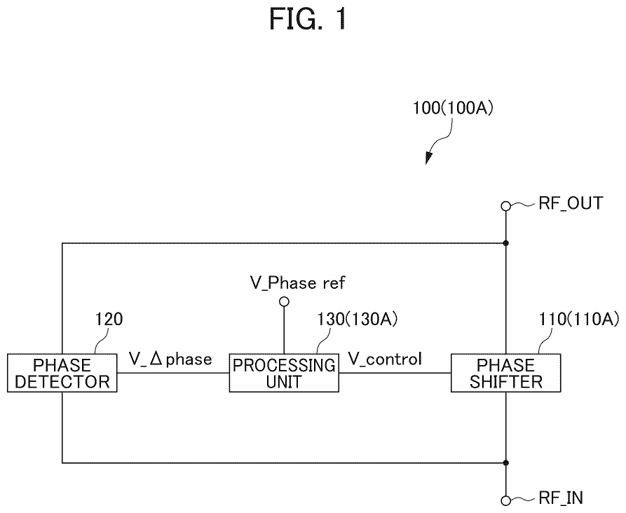

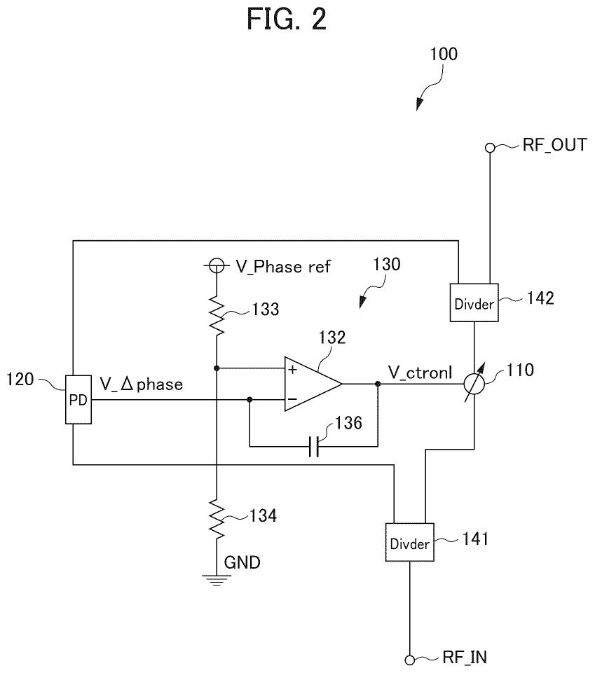

FIG. 1 is a schematic diagram showing an RF phase shifter according to an example embodiment of the present invention, and FIG. 2 is a circuit diagram showing an RF phase shifter according to a first example embodiment of the present invention. An RF phase shifter 100 shown in FIGS. 1 and 2 includes an analog phase shifter 110, a phase detector 120, and an analog processor 130. As shown in FIG. 2, the RF phase shifter 100 may include dividers 141 and 142.

The divider 141 divides the RF signal input to the input terminal RF_IN of the RF phase shifter 100 into an input RF signal of the phase shifter 110 and an input RF signal for the phase detector 120.

The divider 142 divides the output RF signal of the phase shifter 110 into an output RF signal for the phase detector 120 and an output RF signal output from the output terminal RF_OUT of the RF phase shifter 100.

The phase shifter 110 is an analog phase shifter. The phase shifter 110 receives an input RF signal, generates an output RF signal in which the phase of the input RF signal is changed to a set phase according to a control voltage, and outputs the output RF signal.

The phase detector 120 is a highly accurate phase detector. The phase detector 120 compares the phase of the input RF signal with the phase of the output RF signal, and generates a voltage having a voltage value according to the phase difference. This voltage is defined as a phase difference voltage.

The processor 130 is an analog processor and includes an operational amplifier 132. One input of the operational amplifier 132 is connected to the output of the phase detector 120. The other input of the operational amplifier 132 is connected to an intermediate point between resistors 133 and 134 connected in series between the reference voltage line V_Phase ref and the ground line GND. The output of the operational amplifier 132 is feedback-connected to one input of the operational amplifier 132 via a capacitor 136 in series.

The phase difference voltage V_Δphase is input to one input of the operational amplifier 132. The reference voltage V_Phase ref, specifically, the reference voltage V_Phase ref divided by the resistors 133 and 134 is input to the other input of the operational amplifier 132. The reference voltage V_Phase ref is a voltage according to a set phase of the phase shifter 110, for example, a set phase of the output RF signal.

With such a configuration, the processor 130 generates a voltage according to a voltage difference between the phase difference voltage V_Δphase and the reference voltage V_Phase ref. Specifically, the processor 130 integrates the difference voltage between the phase difference voltage V_Δphase and the reference voltage V_Phase ref as shown in the following equation.

V_control=∫(V_Δphase−V_Phase ref)dt

The processor 130 feeds back this voltage as the control voltage V_control to the phase shifter 110.

As described above, according to the RF phase shifter 100 of the first example embodiment, the output phase and the input phase of the phase shifter 110 are compared with each other by the highly accurate phase detector 120, and the difference value between the phase difference and the set phase difference (V_Phase ref) is integrated and fed back to the phase shifter 110 to adjust the output phase to the set phase. This enables highly accurate phase control. Further, the output phase of the output RF signal can be stabilized for a long period of time.

In particular, since the processor 130 performs the integration process, highly accurate phase control is possible even when the frequency of the phase shift target signal becomes high, and the output phase of the output RF signal can be stabilized for a long period of time.

### Second Example Embodiment

### RF Phase Shifter

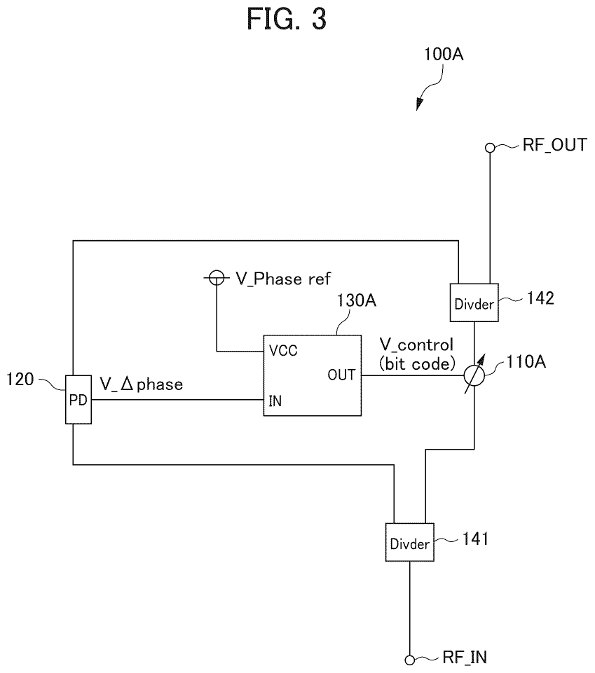

FIG. 1 is a schematic diagram showing an RF phase shifter according to an example embodiment of the present invention, and FIG. 3 is a circuit diagram showing an RF phase shifter according to a second example embodiment of the present invention. An RF phase shifter 100A shown in FIGS. 1 and 3 differs from the RF phase shifter 100 of the first example embodiment shown in FIGS. 1 and 2 in that a digital phase shifter 110A and a digital processor 130A are provided, instead of the analog phase shifter 110 and the analog processor 130.

The phase shifter 110A is a digital phase shifter. The phase shifter 110A receives an input RF signal, generates an output RF signal in which the phase of the input RF signal is changed to a set phase according to a digital control signal, and outputs the output RF signal.

The processor 130A is a digital processor and includes a processor such as, for example, a processor (PU), digital signal processor (DSP), or field-programmable gate array (FPGA). The functions of the processor 130A are achieved by executing predetermined software (program) stored in the memory. The functions of the processor 130A may be achieved by a combination of hardware and software, or may be achieved only by hardware (electronic circuit), for example.

One input of the processor 130A is connected to the output of the phase detector 120, and the other input of the processor 130A is connected to the reference voltage line V_Phase ref. The output of the processor 130A is connected to the phase shifter 110A.

The phase difference voltage V_Δphase is input to one input of the processor 130A. The reference voltage V_Phase ref is input to the other input of the processor 130A. The reference voltage V_Phase ref is a voltage according to a set phase of the phase shifter 110A, for example, a set phase of the output RF signal.

The processor 130A generates a signal according to a voltage difference between the phase difference voltage V_Δphase and the reference voltage V_Phase ref. Specifically, the processor 130A integrates the difference voltage between the phase difference voltage V_Δphase and the reference voltage V_Phase ref as shown in the following equation.

V_control=∫(V_Δphase−V_Phase ref)dt

The processor 130A converts this voltage into a bit code, and feeds back the converted signal to the phase shifter 110A as a digital control signal V_control (bit code).

As described above, also in the RF phase shifter 100A of the second example embodiment, the output phase and the input phase of the phase shifter 110A are compared with each other by the highly accurate phase detector 120, and the difference value between the phase difference and the set phase difference (V_Phase ref) is fed back to the phase shifter 110A, and the output phase is adjusted to the set phase. This enables highly accurate phase control. Further, the output phase of the output RF signal can be stabilized for a long period of time.

In particular, since the processor 130A performs the integration process, highly accurate phase control is possible even when the frequency of the phase shift target signal becomes high, and the output phase of the output RF signal can be stabilized for a long period of time.

### Digital Phase Shifter

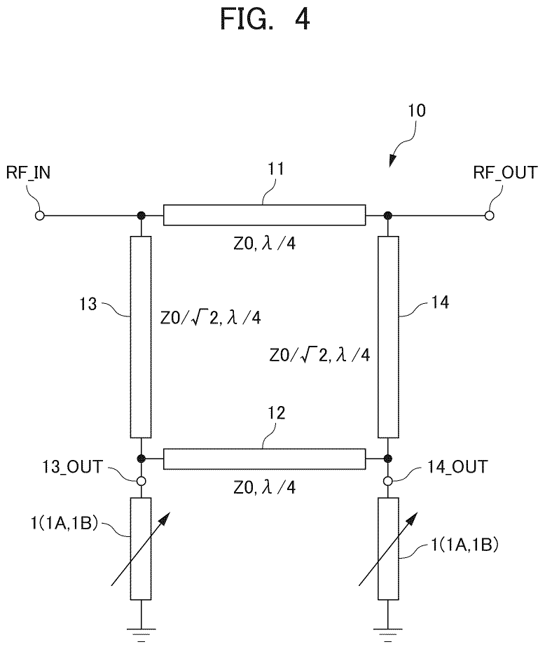

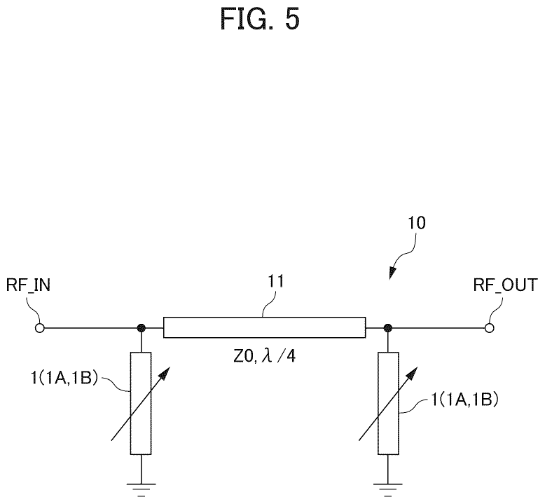

Hereinafter, an example of the digital phase shifter 110A shown in FIG. 3 will be described. FIG. 4 is a circuit diagram showing an example of the phase shifter according to the present example embodiment, and FIG. 5 is a circuit diagram showing another example of the phase shifter according to the present example embodiment. The phase shifter 10 shown in FIG. 4 or 5 can be used as the digital phase shifter 110A shown in FIG. 3.

The phase shifter 10 shown in FIG. 4 is, for example, a hybrid coupled high frequency (RF) phase shifter including ¼ wavelength lines 11 and 12 having a characteristic impedance of Z0 and ¼ wavelength lines 13 and 14 having a characteristic impedance of Z0/√2. The phase shifter 10 includes an input terminal RF_IN at one end of a line 11 and an output terminal RF_OUT at the other end of the line 11. The phase shifter 10 includes variable reactance circuits 1 (1A, 1B) that respectively terminate an output terminal 13_OUT on the line 13 side and an output terminal 14_OUT on the line 14 side. Details of the variable reactance circuits 1 (1A, 1B) will be described later.

In the phase shifter 10, an RF signal input from the input terminal RF_IN is distributed by the hybrid coupled lines 11, 12, 13, and 14, and is transmitted to the output terminal 13_OUT on the line 13 side and the output terminal 14_OUT on the line 14 side. Since these output terminals 13_OUT and 14_OUT are terminated by the variable reactance circuits 1 (1A, 1B), the signals transmitted to these output terminals undergo a phase change dependent on the amount of reactance of the variable reactance circuits 1 (1A, 1B) and are reflected. The signals reflected by the output terminals 13_OUT and 14_OUT are recombined by the hybrid coupled lines 11, 12, 13, and 14, and output from the output terminal RF_OUT. At this time, the output signals undergo a phase change dependent on the amount of reactance of the variable reactance circuits 1 (1A, 1B), and the phase shifter 10 operates as a phase shifter by changing the amount of reactance of the variable reactance circuits.

Although FIG. 4 shows an example in which the variable reactance circuits 1 (1A, 1B) are applied to the hybrid coupled phase shifter 10, as shown in FIG. 5, the variable reactance circuits 1 (1A, 1B) may be applied to a loaded line phase shifter 10 including a ¼ wavelength line 11 having a characteristic impedance of Z0.

As described above, according to the high-frequency phase shifter to which the digital variable reactance circuits described later are applied, since the reactance can be widely varied in both capacitive and inductive characteristics, it is possible to provide a high-frequency (RF) phase shifter having a low loss and a large phase shift width.

### Digital Variable Reactance Circuit

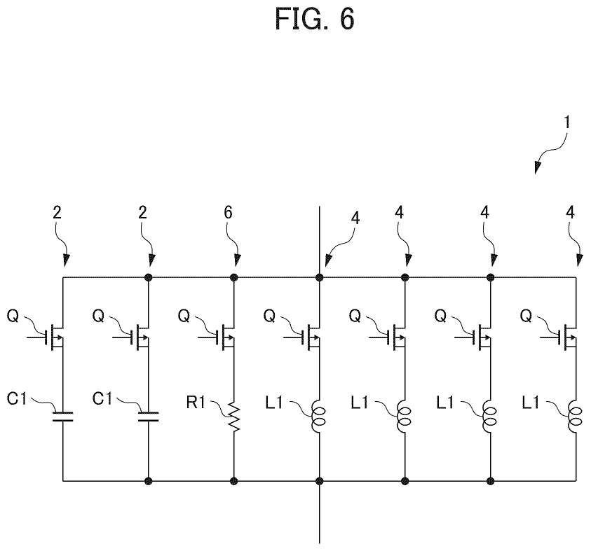

Hereinafter, examples of the variable reactance circuits shown in FIGS. 4 and 5 will be described. FIG. 6 is a circuit diagram showing a digital variable reactance circuit according to the present example embodiment. As shown in FIG. 6, a digital variable reactance circuit 1 digitally varies reactance. The digital variable reactance circuit 1 includes a plurality of digital capacitors 2 and a plurality of digital inductors 4. The digital variable reactance circuit 1 may include a digital resistor 6, for example. In the digital variable reactance circuit 1, the plurality of digital capacitors 2, the plurality of digital inductors 4, and the digital resistor 6 are connected in parallel.

The digital capacitor 2 includes a capacitor C1 and a digital switch (first digital switch) Q connected in series. As the digital switch Q, for example, a switch such as a field effect transistor (FET) is used, although it is not limited. The digital switch Q can be switched between an on state and an off state. This allows the digital capacitor 2 to be switched between a first value, which is the capacitance of the capacitor C1 (the digital switch Q is in the on state), and a second value, which is a capacitance of 0 (the digital switch Q is in the off state). That is, the digital capacitor 2 allows the capacitance to be digitally switched.

The digital inductor 4 includes an inductor L1 and a digital switch (second digital switch) Q connected in series. As the digital switch Q, for example, a switch such as a field effect transistor (FET) is used, although it is not limited. The digital switch Q can be switched between an on state and an off state. This allows the digital inductor 4 to be switched between a first value, which is the inductance of the inductor L1 (the digital switch Q is in the on state), and a second value, which is an inductance of 0 (the digital switch Q is in the off state). That is, the digital inductor 4 allows the inductance to be digitally switched.

The digital resistor 6 includes a resistor R1 and a digital switch Q connected in series. As the digital switch Q, for example, a switch such as a field effect transistor (FET) is used, although it is not limited. The digital switch Q can be switched between an on state and an off state. This allows the digital resistor 6 to be switched between a first value, which is the resistance value of the resistor R1 (the digital switch Q is in the on state), and a second value, which is a resistance value of 0 (the digital switch Q is in the off state). That is, the digital resistor 6 allows the resistance value to be digitally switched.

Thus, the variable reactance circuit 1 can digitally vary the reactance by switching each digital switch Q between an on state and an off state. Further, the variable reactance circuit 1 can digitally vary the impedance, particularly the impedance with respect to the RF signal (high-frequency signal) by switching each digital switch Q between an on state and an off state.

According to the digital variable reactance circuit 1, the reactance of a plurality of capacitors C1 and a plurality of inductors L1 is digitally varied by the control with the digital switch Q. Further, according to the digital variable reactance circuit 1, the impedance of the plurality of capacitors C1, the plurality of inductors L1, and the resistor R1 is digitally varied by the control with the digital switch Q.

In addition, not only the capacitance but also the inductance can be varied, and the reactance can be widely varied in capacitive (½ πfc) and inductive (2 πfL) characteristics. Therefore, the variable width of the reactance (½ πfc+2 πfL) can be widened.

In addition, a plurality of variable capacitors or a plurality of variable inductors are not used, and the control signals of the plurality of variable capacitors or the plurality of variable inductors are not complicated.

Further, it is possible to provide a high frequency (RF) phase shifter having a low loss and a large phase shift width.

In the example embodiment described above, the variable reactance circuit 1 has been exemplified in which each digital capacitor 2 includes the capacitor C1 and the digital switch Q connected in series, each digital inductor 4 includes an inductor and a digital switch connected in series or in parallel, and the plurality of digital capacitors 2 and the plurality of digital inductors 4 are connected in parallel. However, the present invention is not limited thereto, and is applicable to various variable reactance circuits in which each digital capacitor includes a capacitor and a digital switch connected in series or in parallel, each digital inductor includes an inductor and a digital switch connected in series or in parallel, and a plurality of digital capacitors and a plurality of digital inductors are connected in series or in parallel. For example, Modifications 1 and 2 of the present example embodiment will be described below.

### Digital Variable Reactance Circuit of Modification 1

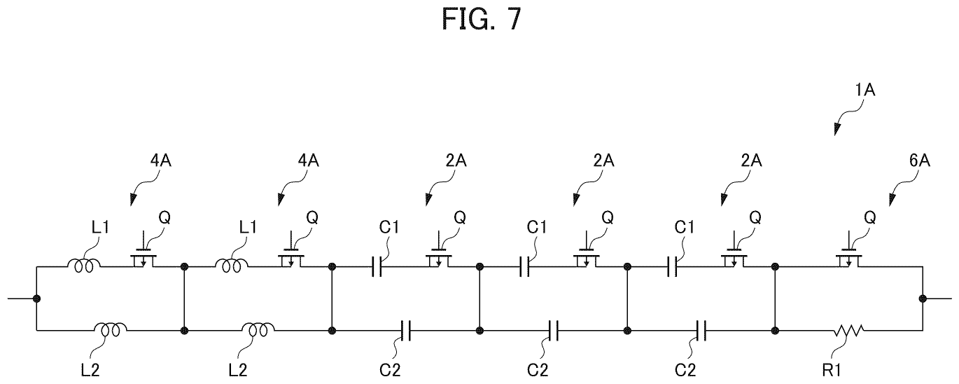

FIG. 7 is a circuit diagram showing a digital variable reactance circuit according to Modification 1 of the present example embodiment. As shown in FIG. 7, a digital variable reactance circuit 1A digitally varies reactance. The digital variable reactance circuit 1A includes a plurality of digital capacitors 2A and a plurality of digital inductors 4A. The digital variable reactance circuit 1A may include a digital resistor 6A. In the digital variable reactance circuit 1A, the plurality of digital capacitors 2A, the plurality of digital inductors 4A, and the digital resistor 6A are connected in series.

The digital capacitor 2A includes a capacitor C1 and a digital switch (first digital switch) Q connected in series, and a capacitor C2 and the digital switch Q connected in parallel. Specifically, in the digital capacitor 2A, the series circuit of the capacitor C1 and the digital switch Q, and the capacitor C2, are connected in parallel. The digital switch Q is, for example, the same as described above. Thus, the digital capacitor 2A can be switched between a first value, which is the combined capacitance of the capacitor C1 and the capacitor C2 (the digital switch Q is in the on state), and a second value, which is the capacitance of the capacitor C2 (the digital switch Q is in the off state). That is, the digital capacitor 2A allows the capacitance to be digitally switched.

The digital inductor 4A includes an inductor L1 and a digital switch (second digital switch) Q connected in series, and an inductor L2 and the digital switch Q connected in parallel. Specifically, in the digital inductor 4A, the series circuit of the inductor L1 and the digital switch Q, and the inductor L2, are connected in parallel. The digital switch Q is, for example, the same as described above. Thus, the digital inductor 4A can be switched between a first value, which is the combined inductance of the inductor L1 and the inductor L2 (the digital switch Q is in the on state), and a second value, which is the inductance of the inductor L2 (the digital switch Q is in the off state). That is, the digital inductor 4A allows the inductance to be digitally switched.

The digital resistor 6A includes a resistor R1 and a digital switch Q connected in parallel. The digital switch Q is, for example, the same as described above. Thus, the digital resistor 6A can be switched between a first value, which is a resistance value of 0 (the digital switch Q is in the on state), and a second value, which is the resistance value of the resistor R1 (the digital switch Q is in the off state). That is, the digital resistor 6A allows the resistance value to be digitally switched.

Thus, in the variable reactance circuit 1A, the reactance can be digitally switched by switching each digital switch Q between an on state and an off state. Further, in the variable reactance circuit 1A, the impedance, particularly the impedance with respect to the RF signal (high-frequency signal), can be digitally varied by switching each digital switch Q between an on state and an off state.

The digital variable reactance circuit 1A of modification 1 also has the same or substantially the same advantages as those of the digital variable reactance circuit 1 of the present example embodiment described above.

### Digital Variable Reactance Circuit of Modification 2

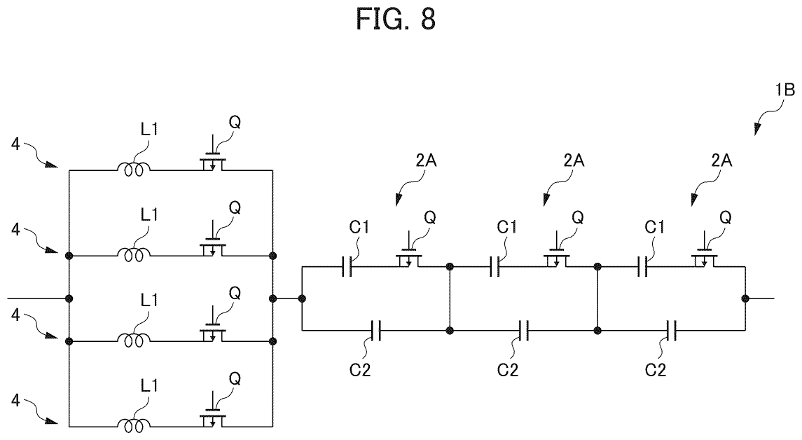

FIG. 8 is a circuit diagram showing a digital variable reactance circuit according to Modification 2 of the present example embodiment. As shown in FIG. 8, a digital variable reactance circuit 1B digitally varies reactance. The digital variable reactance circuit 1B includes a plurality of the digital capacitors 2A and a plurality of the digital inductors 4. In the digital variable reactance circuit 1B, the plurality of the digital capacitors 2A are connected in series, the plurality of the digital inductors 4 are connected in parallel, and the series circuit of the digital capacitors 2A and the parallel circuit of the digital inductors 4 are connected in series.

Accordingly, the variable reactance circuit 1B can digitally vary the reactance by switching each digital switch Q between an on state and an off state. Further, the variable reactance circuit 1B can digitally vary the impedance, particularly the impedance with respect to the RF signal (high-frequency signal) by switching each digital switch Q between an on state and an off state.

The digital variable reactance circuit 1B of Modification 2 also has the same or substantially the same advantages as those of the digital variable reactance circuit 1 of the present example embodiment described above.

Although example embodiments of the present invention and modifications thereof have been described above, the present invention is not limited to the above-described example embodiments, and various modifications and variations are possible. Further, the RF phase shifters of the above-described example embodiments and modifications thereof are applicable to technical fields such as, for example, phased array, radar, synthesizer, and communication.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An RF phase shifter comprising:
a phase shifter to receive an input RF signal, generate an output RF signal in which a phase of the input RF signal is changed to a set phase according to a control voltage, and output the output RF signal;
a phase detector to generate a phase difference voltage according to a phase difference between the input RF signal and the output RF signal; and
a processor to generate the control voltage according to a voltage difference between the phase difference voltage and a reference voltage according to the set phase.

2. The RF phase shifter according to claim 1, wherein the processor is configured to integrate a difference voltage between the phase difference voltage and the reference voltage.

3. The RF phase shifter according to claim 1, wherein the phase shifter is an analog phase shifter.

4. The RF phase shifter according to claim 1, wherein processor is an analog processor.

5. The RF phase shifter according to claim 1, wherein the phase shifter includes:
a first divider to divide the input RF signal into an input RF signal of the phase shifter and an input RF signal of the phase detector; and
a second divider to divide the output RF signal into an output RF signal of the phase detector and an output RF signal of the phase shifter.

6. The RF phase shifter according to claim 1, wherein the processor includes an operational amplifier.

7. The RF phase shifter according to claim 6, wherein the operational amplifier includes an input connected to an output of the phase detector.

8. An RF phase shifter comprising:
a digital phase shifter to receive an input RF signal, generate an output RF signal in which a phase of the input RF signal is changed to a set phase according to a digital control signal, and output the output RF signal;
a phase detector to generate a phase difference voltage according to a phase difference between the input RF signal and the output RF signal; and
a processor to generate the digital control signal according to a voltage difference between the phase difference voltage and a reference voltage according to the set phase.

9. The RF phase shifter according to claim 8, wherein
the digital phase shifter includes a digital variable reactance circuit to digitally vary reactance;
the digital variable reactance circuit includes a plurality of digital capacitors and a plurality of digital inductors;
the plurality of digital capacitors and the plurality of digital inductors are connected in series or in parallel;
each of the plurality of digital capacitors includes a capacitor and a first digital switch connected in series or in parallel, and the first digital switch is switchable between an on state and an off state; and
each of the plurality of digital inductors includes an inductor and a second digital switch connected in series or in parallel, and the second digital switch is switchable between an on state and an off state.

10. The RF phase shifter according to claim 8, wherein the processor is configured to integrate a difference voltage between the phase difference voltage and the reference voltage.

11. The RF phase shifter according to claim 8, wherein the processor is a digital processor.

12. The RF phase shifter according to claim 8, wherein the processor includes a digital signal processor or a field-programmable gate array.

13. The RF phase shifter according to claim 8, wherein the digital phase shifter is a hybrid coupled high frequency phase shifter.

14. The RF phase shifter according to claim 9, wherein the first digital switch includes a field effect transistor.

15. The RF phase shifter according to claim 9, wherein the second digital switch includes a field effect transistor.

16. The RF phase shifter according to claim 9, wherein
the digital variable reactance circuit includes a digital resistor; and
the plurality of digital capacitors, the plurality of digital inductors, and the digital resistor are connected in parallel.

17. The RF phase shifter according to claim 16, wherein the digital resistor includes a resistor and a third digital switch.

18. The RF phase shifter according to claim 17, wherein the third digital switch includes a field effect transistor.
